(19) United States
(12) Patent Application Publication
(10) Pub. No.: US 2012/0025079 A1
(43) Pub. Date: Feb. 2, 2012

(54) INFRARED LED SOURCE FOR THERMAL IMAGING

(76) Inventors: David A. Raulerson, Palm Beach Garden, FL (US); Kevin D. Smith, Glastonbury, CT (US); Zhong Ouyang, Glastonbury, CT (US)

(21) Appl. No.: 12/844,026

(22) Filed: Jul. 27, 2010

(51) Int. Cl. H01L 31/09; H01L 33/58

(52) U.S. Cl. 250/330; 250/504 R

(57) ABSTRACT

A thermal imager has a sensor, a controller, and a flash source. The flash source is an array of IR LEDs. The thermal imager generates a thermal image of a work piece by generating an IR pulse, and sensing the IR radiation from the part.

### BACKGROUND

The present disclosure is related to thermal imaging, and particularly to an LED array for a flash thermography based thermal imaging device.

When inspecting parts for quality control, one aspect reviewed for quality is the thickness of the part. Various techniques are used in the art to determine thickness, and thereby determine if the work piece meets quality control standards. One technique used is thermal imaging via flash thermography. Flash thermography based thermal imagers operate by subjecting the work piece to a short flash of light (a “pulse”) from a flash lamp such as an xenon strobe. A sensor in the thermal imaging device detects Infra-Red (IR) radiation from the heat being emitted from the part, and determines the magnitude of the sensed IR radiation. A controller then creates a thermal image of the work piece based on the magnitude of the sensed IR radiation and the time of maximum occurrence.

### SUMMARY

Disclosed is a thermal imaging device which has an LED flash array, a sensor capable of detecting IR radiation, and a controller. The controller is coupled to the LED flash array and the sensor. The controller is capable of causing the LED flash array to emit a pulse of radiation.

Also disclosed is an LED flash array. The LED flash array has a substantially cylindrical component with a first opening, a substantially cup shaped component with a second opening, and a passageway through the substantially cup shaped component and the substantially cylindrical component that joins the two components, such that electromagnetic radiation may pass through the LED flash array. Arranged about the cup shaped component is a plurality of LED sockets.

Also disclosed is a method for creating a thermal image which has the steps of generating an IR pulse using an array of LEDs which are controlled by a controller, sensing emitted IR radiation using a sensor, and determining the thickness of an object based on the magnitude of the emitted IR radiation.

These and other features of the present invention can be best understood from the following specification and drawings, the following of which is a brief description.

### BRIEF DESCRIPTION OF THE DRAWINGS

FIG. 1 illustrates a schematic example of a thermal imager.

FIG. 1A illustrates a schematic example of a controller for the thermal imager of FIG. 1.

FIG. 2 illustrates another schematic example of a thermal imager.

FIG. 3A illustrates a side view of an example IR LED housing for a thermal imager.

FIG. 3B illustrates a top view of an example IR LED housing for a thermal imager.

FIG. 3C illustrates a bottom view of an example IR LED housing for a thermal imager.

FIG. 4 illustrates a flow chart of a method by which a thermal imager captures a thickness of a part.

### DETAILED DESCRIPTION OF THE PREFERRED EMBODIMENT

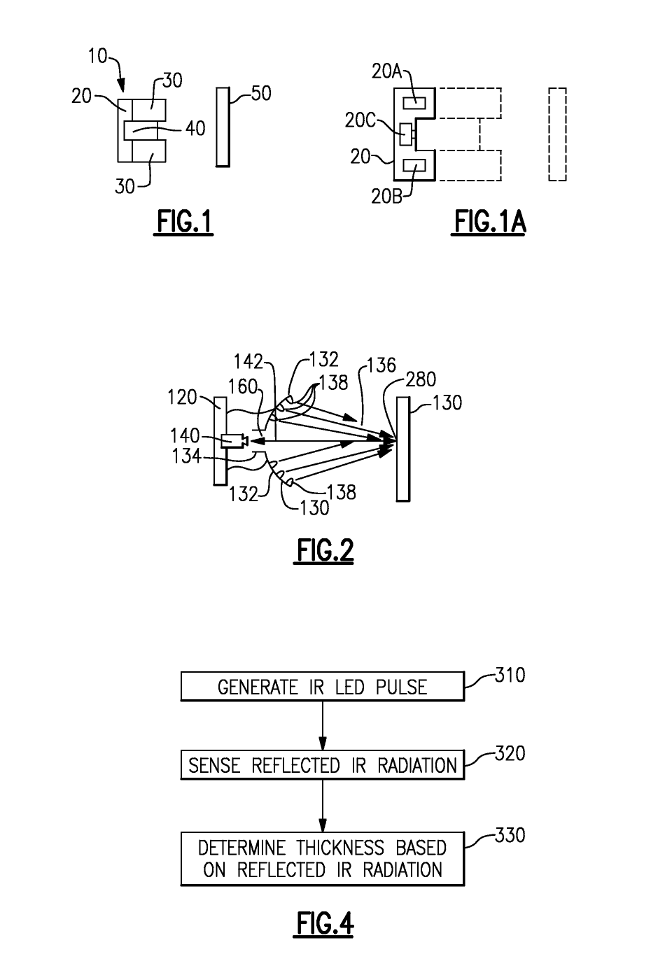

Schematically illustrated in FIG. 1 is an example thermal imaging device 10. The thermal imaging device 10 includes a controller 20, a flash source 30 and an IR sensor 40. In front of the thermal imaging device 10 is a work piece 50. The work piece 50 can be of any shape or material. When the thermal imager 10 is activated, the flash source 30 emits a pulse of IR radiation. The pulse is a short duration pulse. By way of example, the pulse could be under 3 ms. The electromagnetic emissions from the pulse impact the work piece 50. The electromagnetic emissions are absorbed and reflected by the work piece 50 and a portion of the thermal energy radiated by the work piece 50 and strike the sensor 40. The reflected radiation should be minimized.

The sensor 40 detects the magnitude of the IR portion of the emitted electromagnetic emissions, and communicates the magnitude to a controller 20 such as a computer, a microprocessor, or programmable logic controller. The controller 20 also determines the magnitude of the emitted IR radiation from the pulse based on the duration of the pulse and the magnitude of power provided to the flash source 30 during that duration. The controller 20 determines the thickness of the work piece 50 by calculating the Temperature-time curve of the sample surface temperature decay history. The controller 20 can then generate a thermal image of the work piece 50 using known techniques.

IR radiation covers wavelengths of approximately 770 nm to 1 mm, whereas the spectrum emitted by xenon strobe light, as is used in conventional systems, covers the full visible spectrum and ultraviolet spectrum as well as the IR portion of the electromagnetic spectrum. Therefore, when using a xenon strobe to create the IR pulse, a full spectrum burst containing high levels of visible light and UV light along with the IR radiation is created. Such a burst requires a large expenditure of energy creating the pulse in the portions of the electromagnetic spectrum aside from the IR portion. Contrary to the burst created by a xenon strobe, a flash source 30 which is constructed out of an array of IR LEDs will emit minimal radiation outside of the IR portion of the electromagnetic spectrum, thereby reducing energy spent generating electromagnetic radiation outside of the IR portion of the spectrum. IR LEDs are LEDs which emit no visible light and UV light when an electric charge is applied, yet still emit a high magnitude of IR radiation.

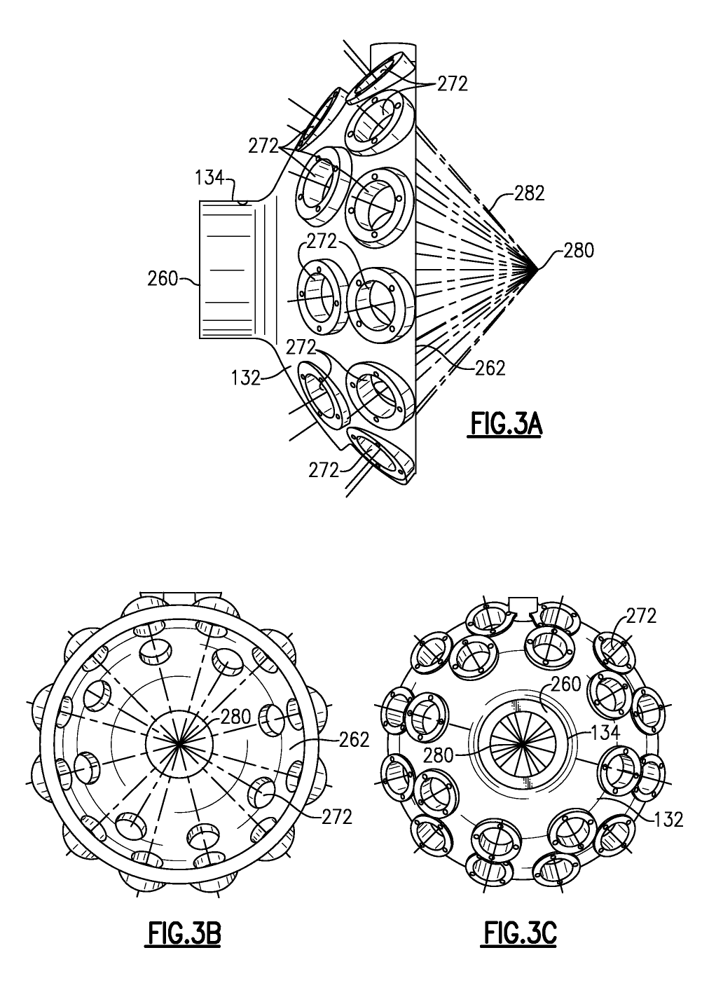

FIG. 2 illustrates another schematic diagram of an example thermal imager 100 using an IR LED array 130 as the flash source. As in the example of FIG. 1, the thermal imager 100 has a sensor 140, a controller 120 and an IR LED array 130 in place of the flash source 30. The IR LED array 130 has a housing with a cup shaped component 132 and a cylindrical component 134. The cup shaped component 134 has multiple LED sockets with installed IR LED's 138 arranged about its surface. The cylindrical component 134 is hollow, thereby allowing IR radiation 142 to pass through the LED array housing and strike the sensor 140. An example physical arrangement of the IR LED array housing is illustrated in FIGS. 3A, 3B, and 3C, and a more detailed description of the example arrangement is provided below.

The sensor 140 is aligned with the cylindrical component 134 such that IR radiation 142 from a pulse that is reflected off the work piece 150, will pass through the cylindrical component 134 and strike the sensor 140. Multiple IR LEDs are arranged on the inside of the cup shaped component 132, and are angled such that emitted IR radiation 136 strikes the work piece 150 at a single focal point 280 which is shared by all the IR LEDs. When the IR radiation 136 strikes the work piece 150, a large portion of the IR radiation is absorbed by the work piece 150, and a small portion reflects off the work piece 150. The sensor 140 senses the magnitude of the emitted IR radiation 142.

The sensor 140 is connected to the controller 120. The controller 120 receives a signal from the sensor 140 when the emitted IR radiation 142 strikes it and determines the magnitude of the emitted IR radiation 142. The controller 120 may also include a simple electrical control circuit for providing and limiting power to the IR LED array 130. The control circuit can be constructed according to any number of known principles using standard components. The controller 120 can additionally determine the magnitude of the IR radiation 136 which was output from the IR LED array 130 based on the duration of the pulse as well as the magnitude of electrical power which was transmitted through the control circuit during the pulse.

FIGS. 3A, 3B, and 3C illustrate an example LED array housing, such as could be used in the example thermal imagers of FIGS. 1 and 2. FIG. 3A illustrates a side view, FIG. 3B illustrates a top view, and FIG. 3C illustrates a bottom view of the IR LED array housing. The IR LED array housing has a cylindrical component 134 and a cup shaped component 132. The cylindrical component 134 has an opening 260 on a first end, and is connected to the cup shaped component 132 at a second end. The cup shaped component 132 has an opening 262 on a first end opposite the cylindrical component 134. The cup shaped component 132 and the cylindrical component 134 are joined at respective second ends. The cylindrical component 134 opening 260 and the cup shaped component 132 opening are connected via a passageway, thereby forming a substantially tube shaped IR LED array housing through which electromagnetic radiation can pass.

Spaced around the cup shaped component 134 are multiple LED sockets 272. In the illustrated example of FIGS. 3A, 3B, and 3C the sockets 272 are arranged in two circular patterns approximately concentric to a cross-section of the first and second openings 260, 262 of the cup shaped component 132 and the cylindrical component 134. The sockets 272 are further arranged such that when LEDs are installed in the sockets 272 and illuminated, each of the LEDs will share at least a single focal point 280 away from the cup shaped component 132. This arrangement is illustrated in the Figures using axis lines 282 which define a vertical axis of each socket opening and a corresponding axis line 282 of each installed LED.

While the LED sockets 272 are arranged such that they share a focal point 280 while illuminated, it is understood that an alternate arrangement could be used which causes a broader beam without a single focal point, thereby encompassing the entire part, and generating an image based on the IR reflection from the broader beam. While the cup shaped component 132 and the cylindrical component 134 are illustrated having concentric circular cross sections, other shaped cross sections could be used, as well as non-concentric cross sections.

Referring again to FIG. 1 a controller 20 executes a thermal imaging process. The functions of the process are disclosed in terms of a functional block diagram (see FIG. 4) and may be executed in either dedicated hardware circuitry, or in a programmed software routine capable of executing in a microprocessor based environment. The controller 20, typically includes a processor 20A, a memory 20B, and an interface 20C. The memory 20B may be any known memory type which is capable of storing instructions for performing the thermal imaging process.

Illustrated in FIG. 4 is a method for generating a thermal image of a work piece using a thermal imager. Initially the thermal imager generates a pulse of IR radiation using an array of IR LEDs which are controlled by a controller in the Generate IR LED Pulse step 310. In order to emit the pulse, the controller allows a short electrical current to pass from a voltage source to the IR LED array, thereby causing the IR LED array to begin emitting radiation. The magnitude of electrical current required to emit the necessary amounts of IR radiation is sufficiently small due to the nature of IR LEDs, and therefore the controller can use standard power circuitry to control the current. The controller allows the IR LEDs to emit radiation for a predetermined duration, typically less than 3 ms, and then prevents electrical power from reaching the IR LED array, thereby stopping the pulse.

During the IR radiation pulse, the IR radiation impacts a work piece which is in front of the thermal imager and a portion of the thermal radiation by the work piece 50 is radiated back toward the thermal imager. The emitted portion of the IR radiation is sensed using a sensor within the thermal imager in the Sense Emitted IR Radiation step 320. The controller is communicatively coupled to the sensor and receives the sensed data. Based on the sensed data, the duration of the pulse, and the magnitude of the electrical power provided during the duration the thermal imager can determine the thickness of the work piece according to known thermal imaging techniques in the Determine Thickness Based on emitted IR Radiation step 330.

While an example method has been illustrated above, it is understood that minor variations to the apparatus or method fall within this disclosure. Such variations include varying the duration of the pulse time, and varying the portion of the electromagnetic spectrum, which is used in the imaging process.

Although example embodiments have been disclosed, a worker of ordinary skill in this art would recognize that certain modifications would come within the scope of this invention. For that reason, the following claims should be studied to determine the true scope and content of this disclosure.

What is claimed is:

1. A thermal imaging device comprising:
an LED flash array;
a sensor capable of detecting IR radiation; and
a controller coupled to said LED flash array and said sensor, said controller capable of causing said LED flash array to emit a pulse of radiation, such that said sensor detects IR radiation radiated off an object in front of said thermal imaging device.

2. The thermal imaging device of claim 1, wherein said LED flash array comprises a housing body having a plurality of LED sockets, and an LED installed in each of said LED sockets.

3. The thermal imaging device of claim 2, wherein each of said LED's is an Infra-Red (IR) LED.

4. The thermal imaging device of claim 3, wherein each of said IR LED's emits IR radiation and radiation across the remainder of the electromagnetic spectrum when a current is applied, and wherein said IR radiation is a high intensity relative to said radiation across the remainder of the electromagnetic spectrum.

5. The thermal imaging device of claim 4, wherein said IR radiation consists essentially of wavelengths in the inclusive range of 770 nm to 1 mm.

6. The thermal imaging device of claim 2, wherein said LED flash array housing has a substantially circular cross section.

7. The thermal imaging device of claim 6, wherein each of said LED sockets is arranged such that each installed LED shares at least one focal point.

8. An LED flash array comprising;
a first opening in a substantially cylindrical component of said LED flash array;
a second opening in a substantially cup shaped component of said LED flash array;
said second opening having a larger circumference than said first opening;
a passageway through said substantially cup shaped component and said substantially cylindrical component, the passageway joins said first and second component such that electromagnetic radiation may pass through said LED flash array; and
a plurality of LED sockets arranged on said cup shaped component.

9. The LED flash array of claim 8, wherein each of said LED sockets comprises electrical connections capable of connecting installed LEDs to a controller.

10. The LED flash array of claim 8, wherein each of said LED sockets are configured about said substantially cup shaped component such that installed LEDs share at least one focal point.

11. The LED flash array of claim 8, wherein said substantially cylindrical component and said substantially cup shaped component are connected via a shared opening.

12. The LED flash array of claim 8, wherein said substantially cylindrical component is tube shaped.

13. A method for creating a thermal image comprising;
generating an infra-red (IR) pulse using an array of LEDs controlled by a controller;
sensing emitted IR radiation using a sensor; and
determining a thickness of an object based on a magnitude of the emitted IR radiation using a controller.

14. The method of claim 13, wherein said step of generating an IR pulse further comprises generating a short electrical current using a controller, thereby causing said IR pulse.

15. The method of claim 14, wherein said electrical current has a duration of less than 3 ms.

16. The method of claim 14, where said electrical current is a low power electrical current.

17. The method of claim 13, wherein said step of generating an IR pulse comprises emitting a radiation pulse which consists essentially of IR radiation.

18. The method of claim 13, wherein said step of generating an IR pulse comprises pulsing a plurality of aligned IR LEDs simultaneously, thereby causing a single pulse.
